(19) United States
(12) Patent Application Publication
(10) Pub. No.: US 2026/0157166 A1
(43) Pub. Date: Jun. 4, 2026

(54) Semiconductor Device and Method of Fabricating the Same

(71) Applicant: UNITED MICROELECTRONICS CORP., Hsin-Chu City (TW)

(72) Inventors: Yao-Hsien Chung, Tainan City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 19/006,063

(22) Filed: Dec. 30, 2024

(30) Foreign Application Priority Data
Dec. 3, 2024 (TW) 113146711

(51) Int. Cl. H01L 23/522; H01L 21/768; H01L 23/00; H01L 23/373; H10D 88/00

(52) U.S. Cl. CPC H10W 20/42; H10W 20/071; H10W 40/258; H10W 72/90; H10D 88/01; H10W 72/01908; H10W 72/01925; H10W 72/981

(57) ABSTRACT

Semiconductor device and method of fabricating the same, includes a substrate, a first dielectric layer and a second dielectric layer, a bonding interface layer, and a plurality of dummy vias. The first dielectric layer and the second dielectric layer are stacked in sequence on the substrate. The bonding interface layer is disposed between the first dielectric layer and the second dielectric layer, wherein the bonding interface layer includes a first interface layer and a second interface layer stacked in sequence. The plurality of dummy vias are disposed within one of the first dielectric layer and the second dielectric layer, being located at only one side of the bonding interface layer in a vertical direction of the substrate.

### BACKGROUND OF THE INVENTION

### 1. Field of the Invention

The present disclosure relates to a semiconductor device, and a method of fabricating the same, and more particularly, to a semiconductor device having dummy vias and a method of fabricating the same.

### 2. Description of the Prior Art

In advanced semiconductor industry, integration density of various electronic components has been continuously improved by reducing minimum feature size, which allows more electronic components to be integrated into given areas. These smaller electronic components also require smaller packages that utilize less area than the conventional packages. Three dimensional integrated circuits (3DICs) refer to a three-dimensional stack of chips formed by using wafer-level bonding and through-silicon-via (TSV) technologies. In comparison with conventional two-dimensional chips, the 3DICs may have the advantages of using the space more effectively, shorter signal transmission distances between chips, and lower interconnecting resistances. The 3DICs have gradually become the mainstream technology of power converters, low noise amplifiers, radio frequency (RF) or millimeter wave (MMW) components. Furthermore, the 3DICs may also be achieved by placing chips over chips of a wafer-level, or forming a bonding interface between the chips by a hybrid bonding process. The hybrid bonding (also known as “metal/dielectric hybrid bonding”) may be a direct bonding technology without using intermediate layers like solder bond or adhesives, which obtains metal-to-metal bonding and dielectric-to-dielectric bonding simultaneously, so as to overcome the fabrication limits of the micro bump technology. However, the current 3DICs still have problems need to be further improved to meet the semiconductor industrial requirements.

### SUMMARY OF THE INVENTION

In light of the above, the present disclosure is directed to provide a semiconductor device and a method of fabricating the same, where a large number of dummy vias are arranged only at a single side of a bonding interface layer, in the region with higher element integration, or the region with more heat concentration, for establishing a heat-dissipation path to fast and easily dissipating the heat, so that, the thermal constrain on the bonding interface layer will be sufficiently improved. In this way, the semiconductor device is allowable to gain a more reliably structure under a simplified fabricating process, so as to quickly remove the heat inside the semiconductor device, and to achieve better performance and operation thereby.

According to an embodiment of the present disclosure, a semiconductor device is provided and includes a substrate, a first dielectric layer and a second dielectric layer, a bonding interface layer, and a plurality of dummy vias. The first dielectric layer and a second dielectric layer are stacked in sequence on the substrate. The bonding interface layer is disposed between the first dielectric layer and the second dielectric layer, wherein the bonding interface layer includes a first interface layer and a second interface layer stacked in sequence. The plurality of dummy vias are disposed within one of the first dielectric layer and the second dielectric layer, being located at only one side of the bonding interface layer in a vertical direction.

According to an embodiment of the present disclosure, a method of fabricating a semiconductor device is provided and includes the following steps. A substrate is provided. A first dielectric layer and a second dielectric layer are formed on the substrate. A bonding interface layer is formed between the first dielectric layer and the second dielectric layer, wherein the bonding interface layer includes a first interface layer and a second interface layer stacked in sequence. A plurality of dummy vias are formed within one of the first dielectric layer and the second dielectric layer, being located at only one side of the bonding interface layer in a vertical direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic cross-sectional diagram of a semiconductor device according to a first embodiment of the present disclosure.

FIG. 2 to FIG. 4 illustrate schematic diagrams of a fabricating method of a semiconductor structure according to a first embodiment of the present disclosure, in which:

FIG. 2 is a schematic cross-sectional view of a semiconductor device after forming dummy vias;

FIG. 3 is a schematic cross-sectional view of a semiconductor device after forming another substrate; and

FIG. 4 is a schematic cross-sectional view of a semiconductor device after forming a bonding interface layer.

FIG. 5 to FIG. 7 illustrate schematic diagrams of a fabricating method of a semiconductor structure according to a second embodiment of the present disclosure, in which:

FIG. 5 is a schematic cross-sectional view of a semiconductor device after forming dummy vias;

FIG. 6 is a schematic cross-sectional view of a semiconductor device after forming a bonding interface layer; and

FIG. 7 is a schematic cross-sectional view of a semiconductor device according to a second embodiment of the present disclosure.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

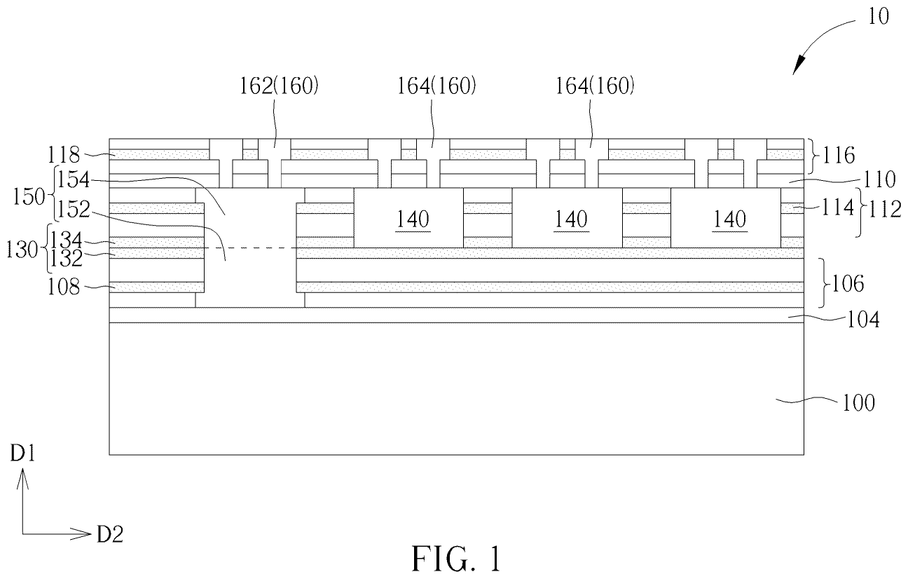

Please refer to FIG. 1, which illustrates a schematic diagram of a semiconductor device 10 according to the first embodiment of the present disclosure. Firstly, as shown in FIG. 1, the semiconductor device 10 includes a substrate 100, a first dielectric layer 106 and a second dielectric layer 112 stacked in sequence on the substrate 100, a bonding interface layer 130 disposed between the first dielectric layer 106 and the second dielectric layer 112, and a plurality of dummy vias 140. The substrate 100 for example includes a wafer level structure or a chip level structure which has been processed through a die saw process, and the substrate 100 may include a silicon material, an epitaxial silicon material, a silicon-containing material such as SiC or a SiGe, a group III-V semiconductor material or any suitable semiconductor material, but not limited thereto. In one embodiment, the first dielectric layer 106 and the second dielectric layer 112 for example include an insulating material like silicon oxide or silicon oxynitride, and the bonding interface layer 130 for example includes an insulating material like silicon nitride or silicon carbonitride, but not limited thereto.

It is noted that, the bonding interface layer 130 precisely includes a first interface layer 132 and a second interface layer 134 stacked in sequence. In the present embodiment, the dummy vias 140 are all disposed within the second dielectric layer 112 and the second interface layer 134 of the bonding interface layer 130, so that, the dummy vias 140 will be all located at the side of the bonging interface layer 130 being away from the substrate 100, as shown in FIG. 1. With these arrangements, the dummy vias 140 may be further coupled to a heat-dissipating element (not shown in the drawings, such as a heat-dissipating pad or a heat-dissipating fin) disposed within the semiconductor device 10, to serve as a heat-dissipation path of the semiconductor device 10, thereby quickly removing the heat inside the semiconductor device 10, especially the heat constrained on the bonding interface layer 130, and then improving the structural reliability of the semiconductor device 10.

Precisely speaking, the semiconductor device 10 further includes an input/output terminal (not shown in the drawings) and a plurality of through silicon vias 160 disposed on the second dielectric layer 112, and a conductive structure 150 disposed within the first dielectric layer 106, the bonding interface layer 130 and the second dielectric layer 112. The input/output terminal is for example disposed at the same side of the bonding interface layer 130 being away from the substrate 100, and the dummy vias 140 disposed within the second dielectric layer 112 are preferably closed to the location of the input/output terminal, such that, the dummy vias 140 are all disposed over the first dielectric layer 106 in a vertical direction D1, as shown in FIG. 1, but not limited thereto. In other words, in the present embodiment, the dummy vias 140 are disposed in a heat-accumulation region of the semiconductor device 10, for example a region closed to the input/output terminal, so as to accelerate the removal of heat inside the semiconductor device 10 through the arrangement of the dummy vias 140, but not limited thereto. In other embodiments, the dummy vias 140 may be optionally disposed only at the another side of the bonding interface layer 130, or disposed at the region with higher element integration within the semiconductor device 10, for excluding a large amount of heat accumulated in a specific region.

The conductive structure 150 precisely includes a first portion 152 and a second portion 154 stacked in sequence in the vertical direction D1, wherein the first portion 152 is for example disposed within the first interface layer 132 of the bonding interface layer 130 and the first dielectric layer 106 at the same time, and the second portion 154 is disposed within the second dielectric layer 112 and the second interface layer 134 of the bonding interface layer 130 at the same time, so that, the border between the first portion 152 and the second portion 154 is just between the first interface layer 132 and the second interface layer 134, but not limited thereto. The through silicon vias 160 are separately disposed in a dielectric layer 116 disposed on the second dielectric layer 112, with a portion of the through silicon vias 160 being electrically connected to the conductive structure 150, to together configure as an interconnection structure (not shown in the drawings) of the semiconductor device 10, with another portion of the through silicon vias 160 being electrically to the dummy vias 140, to together configure as a heat-dissipation path of the semiconductor device 10. In one embodiment, the through silicon vias 160, the conductive structure 150, and the dummy vias 140 for example all include a low-resistance metal material like copper (Cu), aluminum (Al), tungsten (W), or titanium (T1), and preferably including copper, but not limited thereto.

Further in view of FIG. 1, the semiconductor device 10 further includes an insulating layer 104 disposed between the substrate 100 and the first dielectric layer 106, and an insulating layer 110 disposed between the second dielectric layer 112 and the dielectric layer 116. The through silicon vias 160 further penetrates the insulating layer 110, to directly contact the conductive structure 150 and each of the dummy vias 140 respectively. In one embodiment, the insulating layer 104 and the insulating layer 110 for example include an insulating material like silicon oxide, silicon nitride, silicon oxynitride or silicon carbonitride, preferably including an insulating material being different from that of the first dielectric layer 106 and the second dielectric layer 112, but not limited thereto. Furthermore, in one embodiment, the first portion 152 and the second portion 154 of the conductive structure 150, and each through silicon via 160 for example include a dual damascene structure respectively, with the dual damascene further including two portions with different widths in a horizontal direction D2. The first dielectric layer 106, the second dielectric layer 112 and the dielectric layer 116 respectively include a blocking layer 108, 114, 118 additionally disposed therein, to serve as the etching stop layer while forming the dual damascene structure within the first dielectric layer 106, the second dielectric layer 112, and the dielectric layer 116, as shown in FIG. 1. The blocking layer 108, 114, 118 for example includes an insulating material being different from that of the first dielectric layer 106, the second dielectric layer 112 and the dielectric layer 116, such as including silicon nitride or silicon carbonitride, but not limited thereto.

According to the semiconductor device 10 of the present embodiment, a large number of the dummy via 140 are arranged only at a single side of a bonding interface layer 130, serving as the heat-dissipation path of the semiconductor device 10, such that, the heat easily constrained at the bonding interface layer 130 will be fast and effectively removed. Then, the structural reliability of the semiconductor device 10 can be improved, to gain better performance and operation. The dummy vias 140 are preferably disposed at the heat-accumulation region of the semiconductor device 10, for example the region closed to the input/output terminal, so as to accelerate the removal of heat inside the semiconductor device 10 through the arrangement of the dummy vias 140. In addition, people skilled in the art of the present disclosure should easily realize that partial components have been omitted from the drawings in the present embodiment for clearly illustrating the arrangements of the dummy vias, and the semiconductor device 10 may further includes any active component like a transistor, a capacitor or a resistor, or any passive component based on practical product requirements, for serving various functions and performances.

In order to make people skilled in the art of the present disclosure easily understand the semiconductor device 10 of the present disclosure, the fabricating method of the semiconductor device in the present disclosure will be further described below.

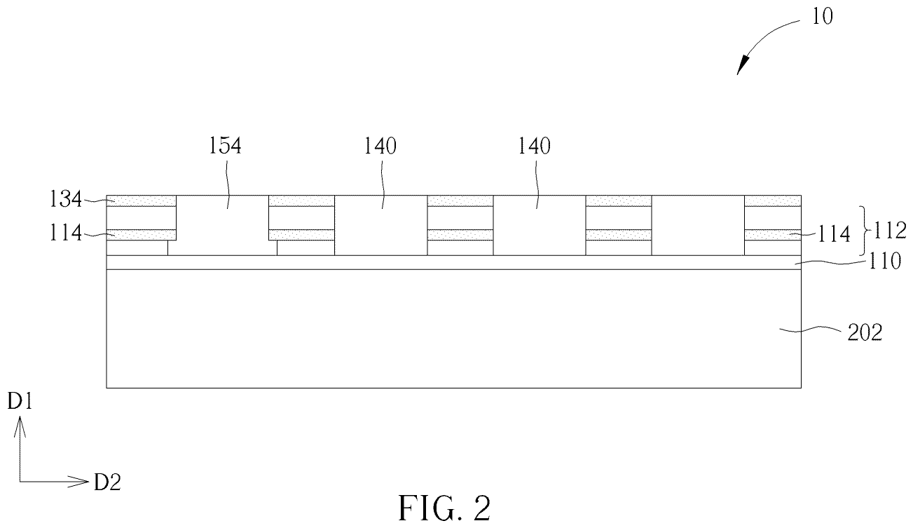

Please refer to FIG. 2 to FIG. 4, illustrating schematic diagrams of a fabricating method of the semiconductor device 10 according to the first embodiment in the present disclosure. Firstly, as shown in FIG. 2, a substrate 202 is provided, for example including a wafer level structure or a chip level structure which has been processed through a die saw process, and the substrate 202 includes a silicon material, an epitaxial silicon material, a silicon-containing material such as SiC or a SiGe, a group III-V semiconductor material or any suitable semiconductor material, but not limited thereto. The insulating layer 110, the second dielectric layer 112 and the second interface layer 134 are sequentially formed on the substrate 202, with the second dielectric layer 112 further including the blocking layer 114 formed therein, and an input/output terminal (not shown in the drawings) is additionally formed on the second dielectric layer 112. In one embodiment, the second interface layer 134 for example includes an insulating material like silicon nitride or silicon carbonitride, the second dielectric layer 112 for example includes an insulating material like silicon oxide or silicon oxynitride, and the blocking layer 114 for example including an insulating material which is different from that of the second dielectric layer 112, like silicon nitride or silicon carbonitride, but not limited thereto. Next, the second portion 154 and the dummy vias 140 are formed within the second interface layer 134 and the second dielectric layer 112.

In one embodiment, the formation of the second portion 154 and the dummy vias 140 includes but not limited to the following steps. Firstly, a patterning process is performed through a mask (not shown in the drawings), to form a first opening (not shown in the drawings) within the second interface layer 134, the second dielectric layer 112, and the blocking layer 114 by using the blocking layer 114 as an etching stop layer, with the second interface layer 134, a portion of the second dielectric layer 112 and the blocking layer 114 being partially removed. Next, an etching process is performed, to further remove another portion of the second dielectric layer 112 disposed under the blocking layer 114, through the first opening, and another patterning process is performed through another mask (not shown in the drawings), to form a plurality of second openings within the second interface layer 134 and the second dielectric layer 112, with the second interface layer 134 and the second dielectric layer 112 (including the blocking layer 114 disposed therein) being partially removed. Then, after completely removing the mask and the another mask, a deposition process and an etching back process are performed, simultaneously filling a conductive material into the first opening and the second openings, to form the second portion 154 and the dummy vias 140 as shown in FIG. 2. The conductive material for example includes a low-resistant metal material like copper, aluminum, tungsten or titanium, and preferably including copper.

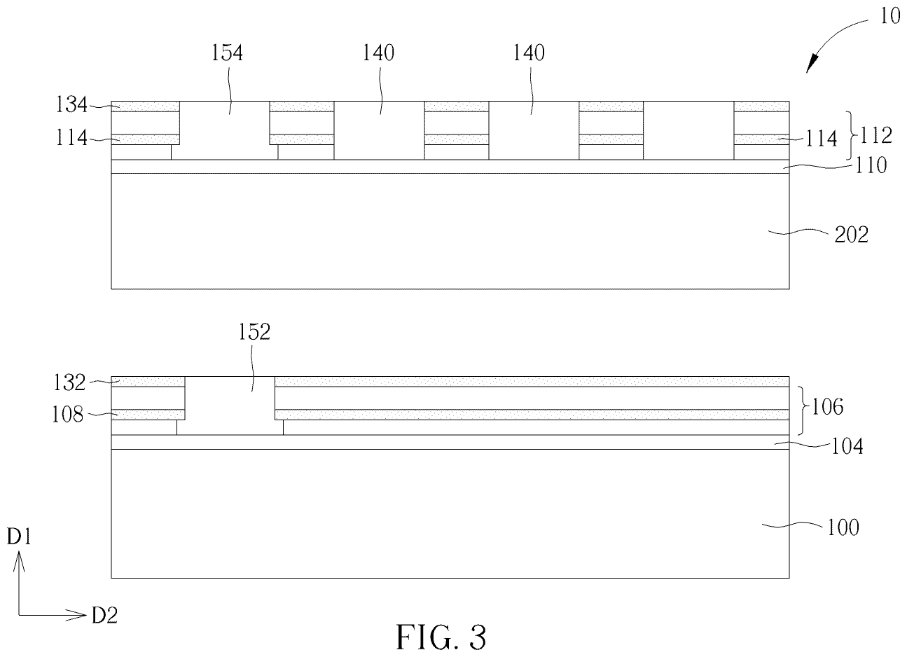

As shown in FIG. 3, another substrate 100 is provided, for example including a wafer level structure or a chip level structure which has been processed through a die saw process, and the substrate 202 includes a silicon material, an epitaxial silicon material, a silicon-containing material such as SiC or a SiGe, a group III-V semiconductor material or any suitable semiconductor material, but not limited thereto. The insulating layer 104, the first dielectric layer 106 and the first interface layer 132 are sequentially formed on the substrate 100, with the first dielectric layer 106 further including the blocking layer 108 formed therein. Next, the first portion 152 is formed within the first interface layer 132 and the first dielectric layer 106. In one embodiment, the formation of the first portion 152 includes but not limited to the following steps. Firstly, a patterning process is performed through a mask (not shown in the drawings), to form an opening (not shown in the drawings) within the first interface layer 132, the first dielectric layer 106 and the blocking layer 108 by using the blocking layer 108 as an etching stop layer, with the first interface layer 132, a portion of the first dielectric layer 106 and the blocking layer 108 being partially removed. Next, an etching process is performed, to further remove another portion of the first dielectric layer 106 disposed under the blocking layer 108, through the opening, and after completely removing the mask, a deposition process and an etching back process are performed, simultaneously filling a conductive material into the opening, to form the first portion 152 as shown in FIG. 3. The conductive material for example includes a low-resistant metal material like copper, aluminum, tungsten or titanium, and preferably including copper.

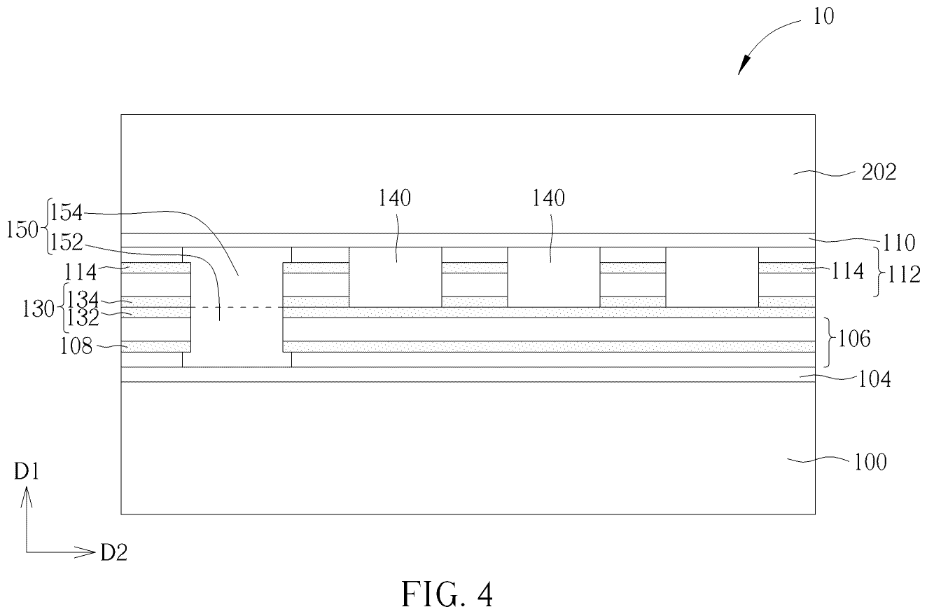

As shown in FIG. 4, the substrate 202 and the substrate 100 are placed on a machine (not shown in the drawings) capable of performing a die bonding process, for bonding the two substrates 202, 100. In the present embodiment, the die bonding process is carried by attaching and bonding the second portion 154 formed on the substrate 202 to the first portion 152 formed on the substrate 100, and also attaching and bonding the second interface layer 134 formed on the substrate 202 to the first interface layer 132 formed on the substrate 100. Accordingly, the first portion 152 and the second portion 154 bonding with each other will together form the conductive structure 150, and the first interface layer 132 and the second interface layer 134 attaching to each other will together form the bonding interface layer 130, such that, components formed on the two substrates 202, 100 are electrically connected with each other. In one embodiment, a wafer thinning process such as a chemical mechanical polishing (CMP) process or an etching process may be optionally performed on the substrate 202 before performing the bonding process, to reduce the thickness of the substrate 202, but not limited thereto.

Following these, the substrate 202 is completely removed, to expose the insulating layer 110, and the dielectric layer 116 and the through silicon vias 160 as shown in FIG. 1 are then formed on the insulating layer 110, to electrically connect to the conductive structure 150 and each dummy via 140. Then, the fabrication of the semiconductor device 10 of the present embodiment is accomplished through the above-mentioned processes. Through these performances, the dummy vias 140 are all disposed at the single one side of the bonding interface layer 130, for example the side closed to the input/output terminal, and which are electrically connected to the through silicon vias 164 formed subsequently, so as to together configure as a heat-dissipation path of the semiconductor device 10. Then, after the bonding process is performed, the heat easily constrained on the bonding interface layer 130 will be fast and effectively removed through the heat-dissipation path.

According to the fabricating method of the semiconductor device 10 in the present embodiment, while forming a portion of the conductive structure 150, the dummy vias 140 are simultaneously formed in the second interface layer 134 and the second dielectric layer 112, to electrically connect to the subsequently formed through silicon vias 164, respectively. Then, the dummy vias 140 and the through silicon vias 160 will together form the heat-dissipation path of the semiconductor device 10. Thus, the semiconductor device 10 is fabricated through a simplified process flow in the fabricating method of the present embodiment, without performing any additional process, and which is capable of fast and effectively removing the heat easily constrained on the bonding interface layer 130 via the heat-dissipation path, thereby accelerating the removal of heat inside the semiconductor device 10, improving the structural reliability of the semiconductor device 10, and further achieving better performance and operation.

People well-skilled in the art should fully understand that the semiconductor device and the fabricating method thereof are not limited to be what is shown in the aforementioned embodiments, and which may further include other examples based on practical product requirements. The following description will detail other different embodiments or variant embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

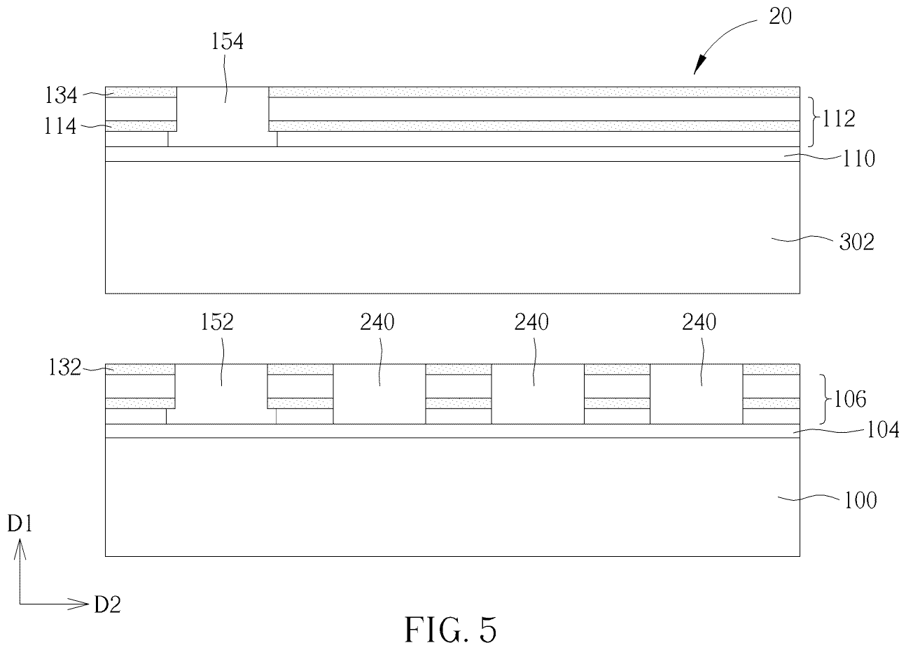

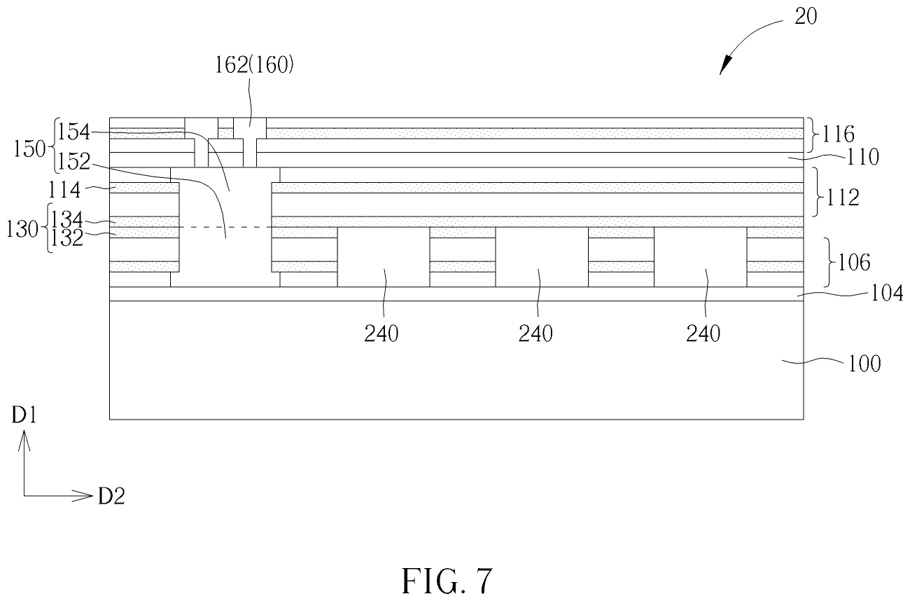

Please refer to FIG. 5 to FIG. 7, illustrating schematic diagrams of a fabricating method of a semiconductor device 20 according to a second embodiment in the present disclosure. The fabricating method of the semiconductor device 20 in the present embodiment is substantially the same as that in the aforementioned embodiment, and all the similarities will not be redundantly described hereinafter. The difference between the present embodiment and the aforementioned embodiment is mainly in that dummy vias 240 of the present embodiment are all disposed within the first interface layer 132 of the bonding interface layer 130 and the first dielectric layer 106, so that, the dummy vias 240 are located only at the side of the bonding interface layer 130 being closed to the substrate 100 in the vertical direction D1, as shown in FIG. 7.

Precisely speaking, as shown in FIG. 5, the substrate 100 is provided, and the insulating layer 104, the first dielectric layer 106 (including the blocking layer 108 formed therein) and the first interface layer 132 are sequentially formed on the substrate 100. Then another substrate 302 is provided, and the insulating layer 110, the second dielectric layer 112 (including the blocking layer 114 formed therein) and the second interface layer 134 are sequentially formed on the another substrate 302. It is noted that, the first portion 152 and a plurality of the dummy vias 240 are formed within the first interface layer 132 and the first dielectric layer 106, with the dummy vias 240 only located within the first interface layer 132 and the first dielectric layer 106, and the second portion 154 is formed within the second interface layer 134 and the second dielectric layer 112.

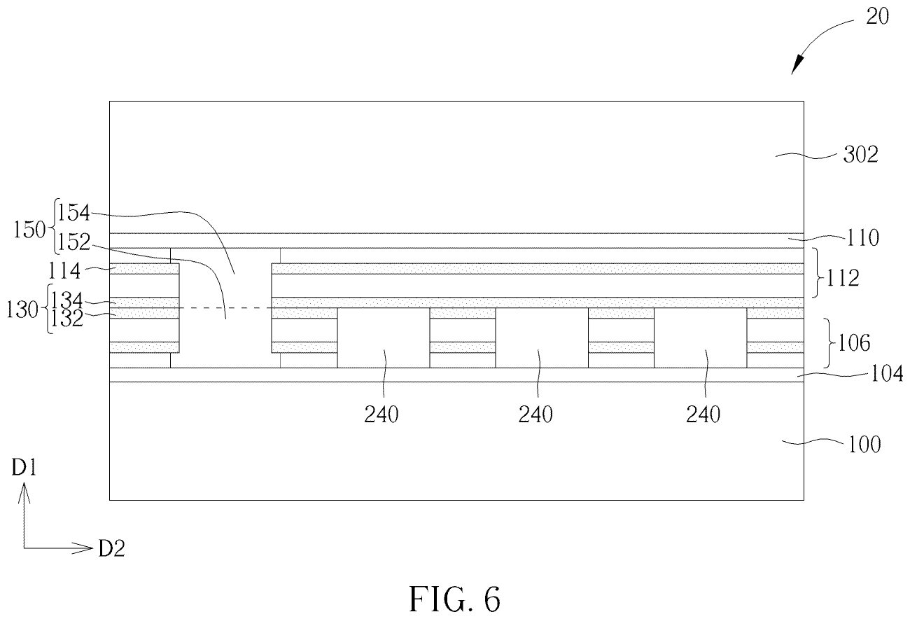

As shown in FIG. 6, the substrate 100 and the substrate 302 are placed on a machine (not shown in the drawings) capable of performing a die bonding process, for bonding the two substrates 100, 302. In the present embodiment, the die bonding process is carried by attaching and bonding the second portion 154 formed on the substrate 302 to the first portion 152 formed on the substrate 100, and also attaching and bonding the second interface layer 134 formed on the substrate 302 to the first interface layer 132 formed on the substrate 100. Accordingly, the first portion 152 and the second portion 154 bonding with each other will still form the conductive structure 150, and the first interface layer 132 and the second interface layer 134 attaching to each other will still form the bonding interface layer 130, with the components formed on the two substrates 302, 100 being electrically connected with each other.

After that, as shown in FIG. 7, the substrate 302 is completely removed, to expose the insulating layer 110, and the dielectric layer 116 (including the blocking layer 118 formed therein) and the through silicon vias 160 are then formed on the insulating layer 110, to electrically connect to the conductive structure 150. Then, the fabrication of the semiconductor device 20 of the present embodiment is accomplished through the above-mentioned processes. Through these performances, the dummy vias 240 are all disposed at the single one side of the bonding interface layer 130, especially the side closed to the substrate 100, and which are covered by the second interface layer 134 in the vertical direction D1. Accordingly, the dummy vias 240 may be next electrically connected to a metal interconnection structure (not shown in the drawings) formed on the substrate 100, followed by further electrically connecting to a heat-dissipating element (not shown in the drawings, such as a heat-dissipating pad or a heat-dissipating fin), such that, the dummy vias 240 and the metal interconnection structure may also form a heat-dissipation path of the semiconductor device 20, to accelerate the removal of heat inside the semiconductor device 20, especially the heat easily accumulated at the region with relative higher element integration, and to improving the structural reliability of the semiconductor device 20 thereby.

According to the fabricating method of the semiconductor device 20 in the present embodiment, while forming a portion of the conductive structure 150, the dummy vias 240 are simultaneously formed in the first interface layer 132 and the first dielectric layer 106. Then, the dummy vias 240 are all disposed at the same side of the bonging interface layer 130, after the bonding process, with the dummy vias 240 serving as the heat-dissipation path of the semiconductor device 20. Thus, the semiconductor device 20 fabricated through the fabricating method of the present embodiment enables of fast and effectively removing the heat easily constrained on the bonding interface layer 130 via the heat-dissipation path, thereby accelerating the removal of heat inside the semiconductor device 20, improving the structural reliability of the semiconductor device 20, and achieving better performance and operation.

Overall speaking, through the semiconductor device and the fabricating method thereof in the present disclosure, a large number of dummy via is arranged only at a single side of a bonding interface layer, in the region with relative higher element integration, or in the region with more heat concentration, for establishing a heat-dissipation path, so that, the thermal constrain possibly occurred on the bonding interface layer will be sufficiently improved. In this way, the semiconductor device is allowable to gain a more reliably structure under a simplified fabricating process, so as to quickly remove the heat inside the semiconductor device, and to achieve better performance and operation.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package, comprising:
a substrate;
a first dielectric layer and a second dielectric layer stacked in sequence on the substrate;
a bonding interface layer, disposed between the first dielectric layer and the second dielectric layer, wherein the bonding interface layer comprises a first interface layer and a second interface layer stacked in sequence; and
a plurality of dummy vias, disposed within one of the first dielectric layer and the second dielectric layer, being located at only one side of the bonding interface layer in a vertical direction.

2. The semiconductor device according to claim 1, wherein the plurality of dummy vias are disposed within the second dielectric layer and the second interface layer, over the first dielectric layer in the vertical direction.

3. The semiconductor device according to claim 1, wherein the plurality of dummy vias are disposed within the first dielectric layer and the first interface layer, and the plurality of dummy vias are covered by the second interface layer in the vertical direction.

4. The semiconductor device according to claim 1, further comprising:
a conductive structure, disposed within the first dielectric layer, the bonding interface layer and the second dielectric layer, wherein the conductive structure comprises a first portion and a second portion stacked in sequence in the vertical direction.

5. The semiconductor device according to claim 2, further comprising:
a plurality of through silicon vias, disposed on the second dielectric layer, wherein a portion of the plurality of through silicon vias are electrically connected to the plurality of dummy vias.

6. The semiconductor device according to claim 5, wherein the plurality of through silicon vias and the plurality of dummy vias both comprise copper.

7. The semiconductor device according to claim 2, further comprising:
an input/output terminal disposed on the second dielectric layer, adjacent to the plurality of dummy vias disposed within the second dielectric layer.

8. A method of fabricating a semiconductor device, comprising:
providing a substrate;
forming a first dielectric layer and a second dielectric layer on the substrate;
forming a bonding interface layer between the first dielectric layer and the second dielectric layer, wherein the bonding interface layer comprising a first interface layer and a second interface layer stacked in sequence; and
forming a plurality of dummy vias within one of the first dielectric layer and the second dielectric layer, being located at only one side of the bonding interface layer in a vertical direction.

9. The method of fabricating the semiconductor device according to claim 8, further comprising:
providing another substrate;
respectively forming the first dielectric layer and the second dielectric layer on the substrate and the another substrate;
forming the first interface layer on the first dielectric layer;
forming the second interface layer on the second dielectric layer; and
bonding the second interface layer and the first interface layer, to form the bonding interface layer.

10. The method of fabricating the semiconductor device according to claim 9, forming the plurality of dummy vias further comprising:
forming the plurality of dummy vias within the second dielectric layer and the second interface layer, wherein after bonding the second interface layer and the first interface layer, the plurality of dummy vias are over the first interface layer.

11. The method of fabricating the semiconductor device according to claim 10, after forming the plurality of dummy vias in the second dielectric layer and the second interface layer, further comprising:
forming an input/output terminal on the another substrate.

12. The method of fabricating the semiconductor device according to claim 9, forming the plurality of dummy vias further comprising:
forming the plurality of dummy vias within the first dielectric layer and the first interface layer, wherein after bonding the second interface layer and the first interface layer, the plurality of dummy vias are covered by the second interface layer.

13. The method of fabricating the semiconductor device according to claim 9, further comprising:
forming a conductive structure within the first dielectric layer, the bonding interface layer and the second dielectric layer, wherein the conductive structure comprises a first portion and a second portion stacked in sequence.

14. The method of fabricating the semiconductor device according to claim 10, further comprising:
forming a plurality of through silicon vias on the second dielectric layer, wherein a portion of the plurality of through silicon vias are electrically connected to the plurality of dummy vias.

15. The method of fabricating the semiconductor device according to claim 9, after forming the dummy vias further comprising:
completely removing the another substrate after bonding the second interface layer and the first interface layer.
